(19) United States
(12) Patent Application Publication
(10) Pub. No.: US 2024/0006500 A1
(43) Pub. Date: Jan. 4, 2024

(54) STACKED COMBSHEET FIELD EFFECT TRANSISTOR

(71) Applicant: International Business Machines Corporation, Armonk, NY (US)

(72) Inventors: Tsung-Sheng Kang, Ballston Lake, NY (US); Ruqiang Bao, Niskayuna, NY (US); Curtis S. Durfee, Schenectady, NY (US); Tao Li, Slingerlands, NY (US)

(21) Appl. No.: 17/855,411

(22) Filed: Jun. 30, 2022

(51) Int. Cl. H01L 29/423; H01L 29/06; H01L 29/786; H01L 27/088; H01L 29/04; H01L 21/822; H01L 21/8234

(52) U.S. Cl. CPC H01L 29/42392; H01L 29/0676; H01L 29/78696; H01L 27/088; H01L 29/045; H01L 21/8221; H01L 21/823412

(57) ABSTRACT

An integrated circuit structure includes a first combsheet field effect transistor (FET), which includes: a semiconductor substrate; a first plurality of semiconductor nanosheets that extend along a <101> crystallographic direction and that have horizontal surfaces oriented in (100) crystallographic planes and vertical sidewalls oriented in (110) crystallographic planes; and a semiconductor fin that is integrally attached to the nanosheets, extends along the nanosheets, and has horizontal sidewalls oriented in (100) crystallographic planes and vertical surfaces oriented in (110) crystallographic planes.

### BACKGROUND

The present invention relates to the electrical, electronic, and computer arts, and more specifically, to semiconductor devices and their fabrication.

Referring to FIG. 1 and FIG. 2, a FinFET (fin-type Field Effect Transistor) 100 and a nanosheet FET 200 are two types of FET that are used in complex semiconductor devices, i.e., integrated circuits. It is desirable for the mobilities of holes and electrons through a FET to be substantially the same.

Referring to FIG. 3, a chart 300 shows that mobilities of electrons and holes in FinFET 100 and in nanosheet FET 200 are different due to differing arrangements of crystallographic planes in the epitaxially grown fin 104 as compared to the epitaxially grown nanosheets 204. Generally, holes are more mobile across a (110) crystallographic plane, whereas electrons are more mobile across a (100) crystallographic plane.

### SUMMARY

Principles of the invention provide techniques for a stacked combsheet field effect transistor.

In an aspect, an exemplary integrated circuit structure includes a first combsheet field effect transistor (FET), which includes: a semiconductor substrate; a first plurality of semiconductor nanosheets that extend along a <101> crystallographic direction and that have horizontal surfaces oriented in (100) crystallographic planes and vertical sidewalls oriented in (110) crystallographic planes; and a semiconductor fin that is integrally attached to the nanosheets, extends along the nanosheets, and has horizontal sidewalls oriented in (100) crystallographic planes and vertical surfaces oriented in (110) crystallographic planes.

In another aspect, an exemplary method for forming a combsheet field effect transistor (FET) includes providing a semiconductor substrate; epitaxially growing, from the semiconductor substrate, a first plurality of stacked semiconductor nanosheets that are interleaved with a first plurality of stacked sacrificial layers, by alternately depositing a first semiconductor that forms the nanosheets and depositing a sacrificial semiconductor that forms the sacrificial layers between the nanosheets; etching a trench into the stacked plurality of semiconductor nanosheets and sacrificial layers; and epitaxially growing a semiconductor fin from sidewalls of the nanosheets into the trench, such that vertical surfaces of the fin are oriented in (110) crystallographic planes and horizontal surfaces of the nanosheets are oriented in (100) crystallographic planes, such that the fin and the nanosheet integrally attached to the fin compose the combsheet FET.

In view of the foregoing, techniques of the present invention can provide substantial beneficial technical effects. For example, one or more embodiments provide one or more of:

A stacked CMOS (complementary metal oxide semiconductor) FET with reduced difference between hole and electron mobility in the pFET and nFET portions of the CMOS.

A CMOS FET with increased effective width due to an extra fin channel attached to the nanosheets, which is beneficial for both hole and electron mobility.

A CMOS FET with additional (110) crystal plane surfaces that are particularly beneficial for pFET hole mobility.

Some embodiments may not have these potential advantages and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 depicts a prior-art field effect transistor (FET) with a fin-shaped source-channel-drain configuration (a FinFET).

FIG. 2 depicts a prior-art FET with source-channel-drain formed by layered nanosheets (a nanosheet FET).

FIG. 3 depicts a chart of hole and electron mobility in the FinFET of FIG. 1 and in the nanosheet FET of FIG. 2.

FIG. 4 depicts differing arrangements of crystallographic planes in the FinFET that is shown in FIG. 1 and in nanosheet FETs like that shown in FIG. 2.

FIGS. 5, 5A, 5B, 5C depict a stacked combsheet FET, according to exemplary embodiments.

FIG. 6 through FIG. 19 depict other stacked combsheet FETs, according to exemplary embodiments.

FIG. 20A, 20B, 21A, 21B, 22A, 22B, 23A, 23B, 24A, 24B, 24C, 25A, 25B, 25C, 26A, 26B, 26C, 27A, 27B, 27C depict intermediate structures in a method of making the stacked combsheet FET that is shown in FIG. 5, 5A, 5B, 5C. Each A, B, or C figure corresponds to a cutline X, Y, or M in FIG. 5.

FIG. 28, 28A, 28B, 28C depict a bonded wafer structure of a stacked combsheet FET, according to exemplary embodiments.

FIG. 29A, 29B, 29C, 30A, 30B, 30C, 31 depict intermediate structures in a method of making the stacked combsheet FET that is shown in FIG. 28, 28A, 28B, 28C. Each A, B, or C figure corresponds to a cutline X, Y, or M in FIG. 28.

### DETAILED DESCRIPTION

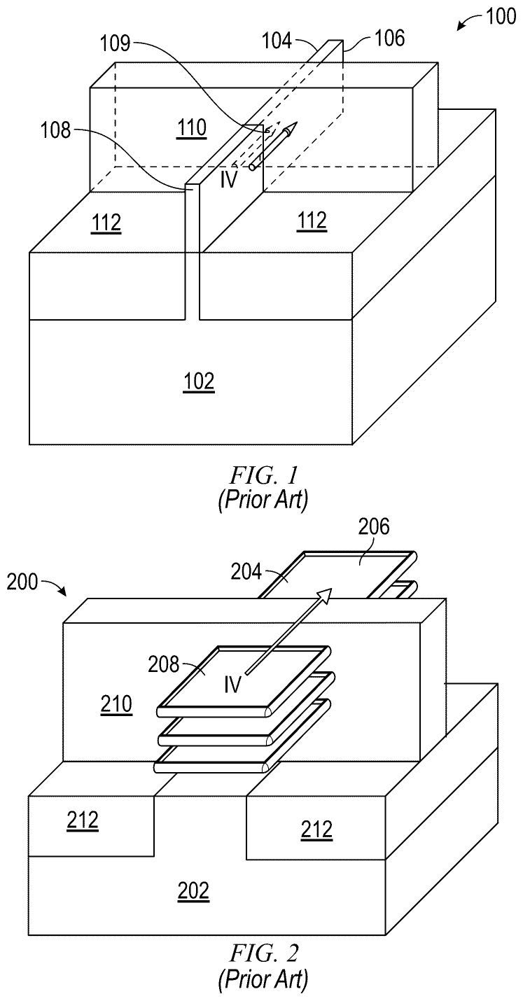

FIG. 1 depicts a FinFET 100. The FinFET 100 includes a semiconductor substrate 102 (typically, silicon) from which a fin 104 has been epitaxially grown. The fin includes first and second source/drain ends 106, 108. The source/drain ends are interchangeable, according to how the FinFET 100 is electrically connected to other circuitry (not shown). The fin 104 also includes a channel 109, which passes through a gate stack 110 to connect the source/drain ends 106, 108. In one or more embodiments, the gate stack 110 may be a high-k metal gate (HKMG) stack, further discussed below. A dielectric 112 surrounds the fin 104 and separates it from adjoining fins. Portions of the dielectric 112 are not shown so as to reveal the fin and gate.

FIG. 2 depicts a nanosheet FET 200. The nanosheet FET includes a substrate 202, from which a stack of nanosheets 204 have been epitaxially grown. The nanosheets 204 include electrically interchangeable source/drain ends 206, 208 that are connected by channels, which pass through a gate stack 210. In one or more embodiments, the gate stack 210 may be a high-k metal gate (HKMG) stack, further discussed below. A dielectric 212 surrounds the nanosheets 204 and separate them from adjoining nanosheets. Portions of the dielectric 212 are not shown so as to reveal the nanosheets and gate.

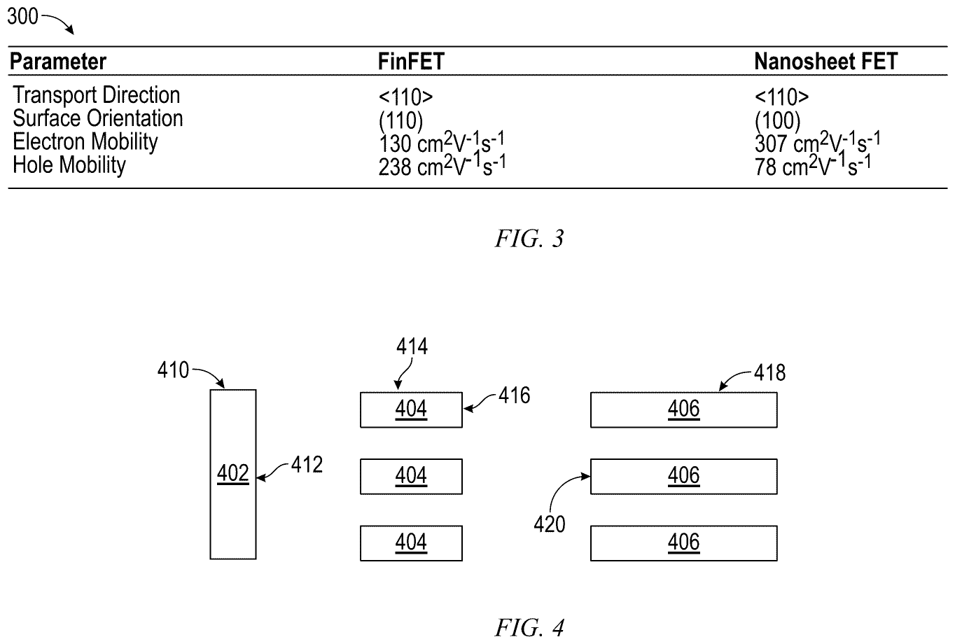

FIG. 3 depicts a chart 300 of hole and electron mobility in the FinFET of FIG. 1 and the nanosheet FET of FIG. 2.

FIG. 4 depicts differing arrangements of crystallographic planes in a FinFET 402 like that which is shown in FIG. 1 and in nanosheet FETs 404, 406 like those which are shown in FIG. 2. Surfaces 412, 414, 418 of the FinFET 402 and of the nanosheets 404, 406 are oriented with (110) crystallography. Sidewalls 410, 416, 420 of the FinFET 402 and of the nanosheets 404, 406 are oriented with (100) crystallography.

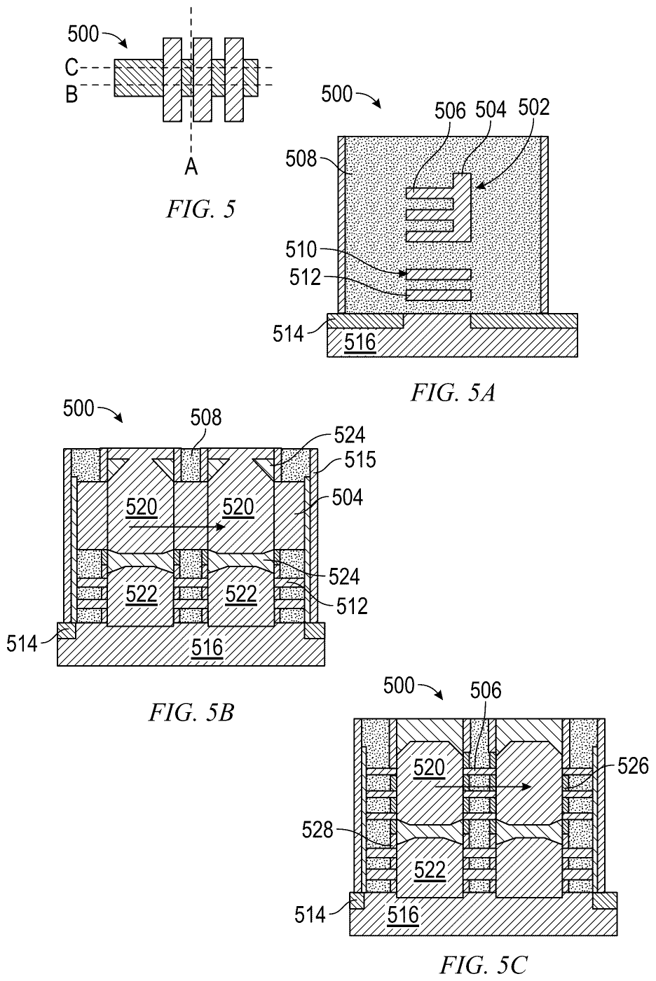

FIGS. 5, 5A, 5B, 5C depict a stacked combsheet FET 500, according to exemplary embodiments. Views 5A, 5B, 5C (and subsequent X, Y, M views of intermediate structures in a method of making the stacked combsheet 500) are taken along cutlines X, Y, and M in FIG. 5. The stacked combsheet FET 500 includes a first combsheet channel structure 502, which in turn includes a fin 504 that has nanosheets 506 protruding from a surface of the fin. In gate-all-around fashion, a gate stack 508 surrounds the first combsheet 502 and a nanosheet channel structure 510, under the first combsheet. The nanosheet channel structure 510 includes a plurality of nanosheets 512. In one or more embodiments, the gate stack 508 may be a high-k metal gate (HKMG) stack, further discussed below. The stacked combsheet FET 500 also includes shallow trench isolation (STI) 514. A liner 515 isolates vertical surfaces of the stacked combsheet 500 from adjoining FETs (not shown). The stacked combsheet FET 500 is built on a semiconductor substrate 516. Upper and lower source/drain structures 520, 522 are grown epitaxially from the substrate 516. Interlayer dielectric 524 separates the upper and lower source/drain structures. Spacers 526, 528 separate the gate stack 508 from the source/drains.

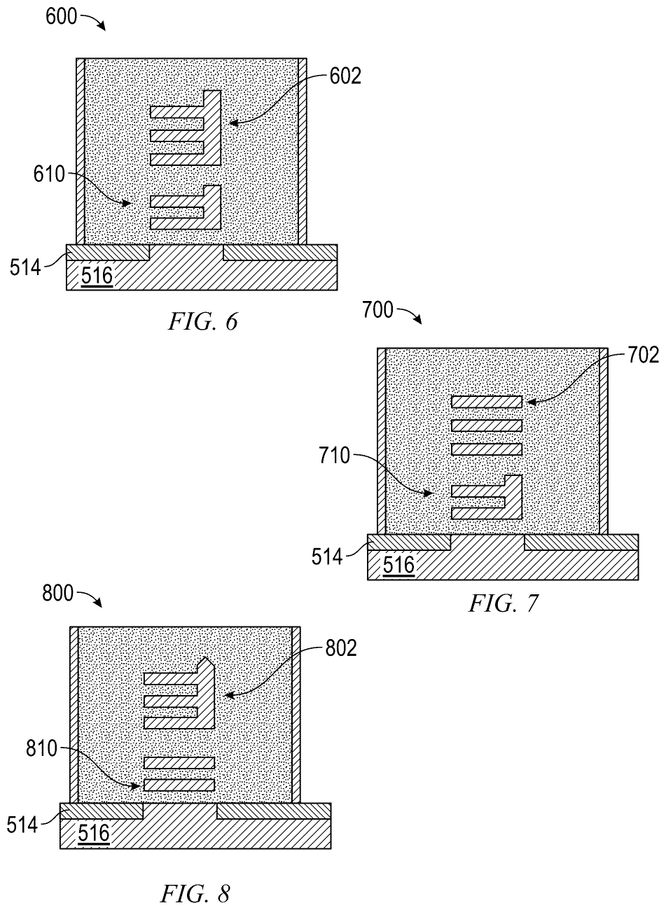

FIG. 6 through FIG. 19 depict other stacked combsheet FETs, according to exemplary embodiments.

A FET 600, as shown in FIG. 6, includes first and second combsheet channel structures 602, 610 that are vertically stacked.

A FET 700, as shown in FIG. 7, includes a nanosheet channel structure 702 that is stacked above a combsheet channel structure 710.

A FET 800, as shown in FIG. 8, includes a combsheet channel structure 802 that has a peaked fin, and a nanosheet channel structure 810 that is stacked under the combsheet channel structure 802.

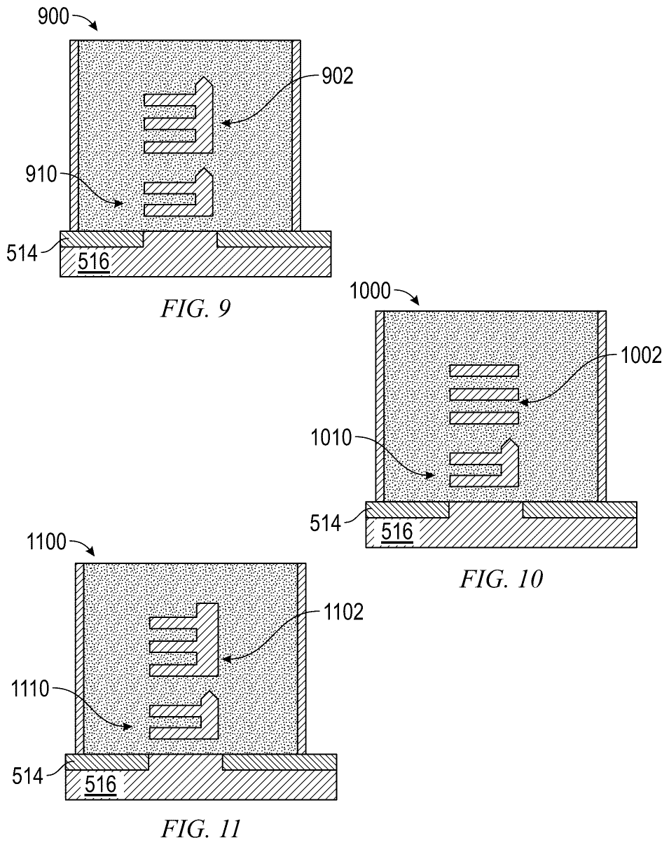

FIG. 9 shows a FET 900, which includes two stacked combsheet channel structures 902, 910, each of which has a peaked fin.

A FET 1000, as shown in FIG. 10, includes a nanosheet channel structure 1002 that is stacked above a combsheet channel structure 1010, which has a peaked fin.

In FIG. 11, a FET 1100 includes a first combsheet channel structure 1102 that is stacked above a second combsheet channel structure 1110, which has a peaked fin.

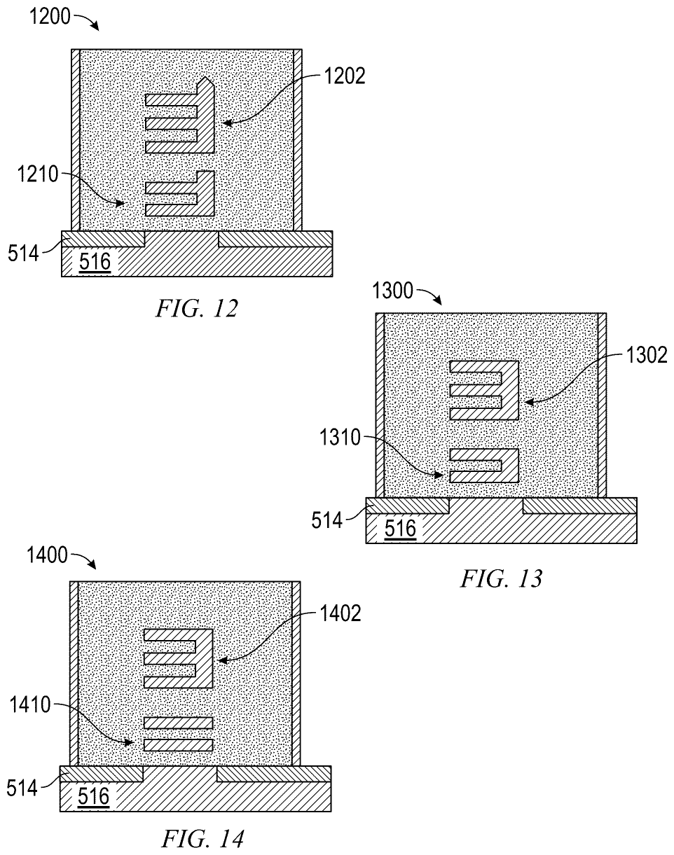

A FET 1200, as shown in FIG. 12, includes a first combsheet channel structure 1202, which has a peaked fin. In the FET 1200, the first combsheet channel structure 1202 is stacked above a second combsheet channel structure 1210.

FET 1300, as shown in FIG. 13, includes first and second combsheet channel structures 1302, 1310, which are vertically stacked; in the FET 1300, the tops of the fins are flush with upper surfaces of the upper nanosheets.

A FET 1400, as shown in FIG. 14, includes a combsheet channel structure 1402, in which the top of the fin is flush with the upper surface of the upper nanosheet; the combsheet channel structure 1402 is stacked above a nanosheet channel structure 1410.

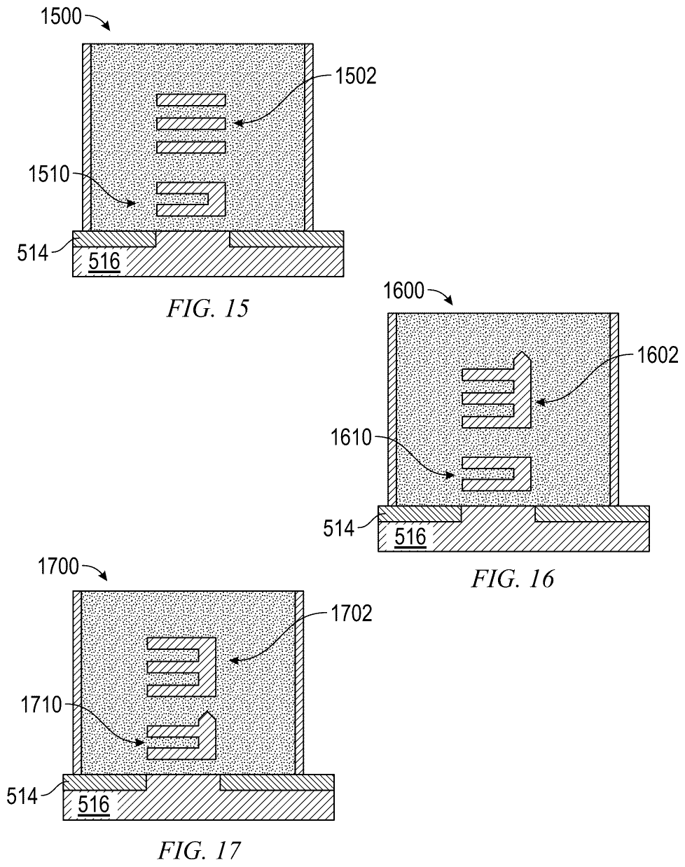

In FIG. 15, a FET 1500 includes a nanosheet channel structure 1502 that is stacked above a combsheet channel structure 1510. In the combsheet channel structure 1510, the top of the fin is flush with an upper surface of the upper nanosheet.

In FIG. 16, a FET 1600 includes a first combsheet channel structure 1602 that is stacked above a second combsheet channel structure 1610. The fin of the first combsheet channel structure 1602 has a peaked top, whereas the fin of the second combsheet channel structure 1610 has a top that is flush with an upper surface of the upper nanosheet.

FIG. 17 shows a FET 1700 in which an upper combsheet channel structure 1702 is stacked above a lower combsheet nanochannel structure 1710. The fin of the upper combsheet channel structure has a top that is flush with an upper surface of the upper nanosheet. The fin of the lower combsheet channel structure has a peaked top.

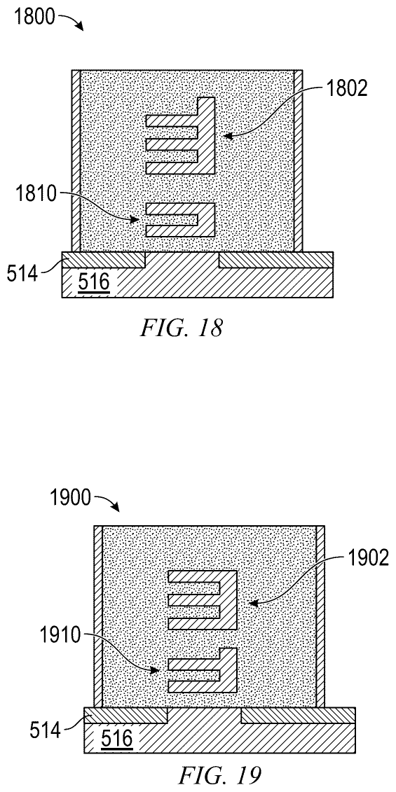

FET 1800, as shown in FIG. 18, has an upper combsheet channel structure 1802 and a lower combsheet channel structure 1810. The top of the fin in the lower combsheet channel structure is flush with an upper surface of the top nanosheet.

In FIG. 19, a FET 1900 has an upper combsheet channel structure 1902, in which the top of the fin is flush with an upper surface of the top nanosheet. The FET 1900 also has a lower combsheet channel structure 1910.

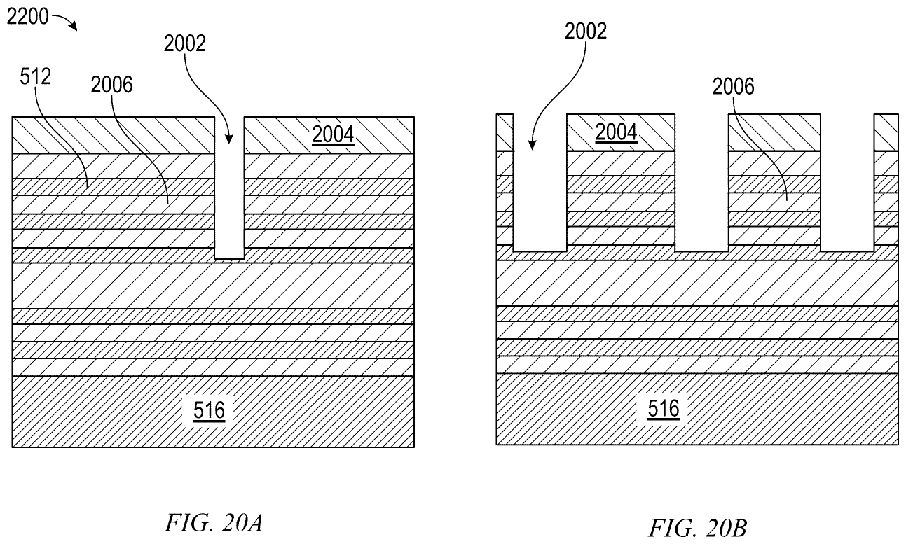

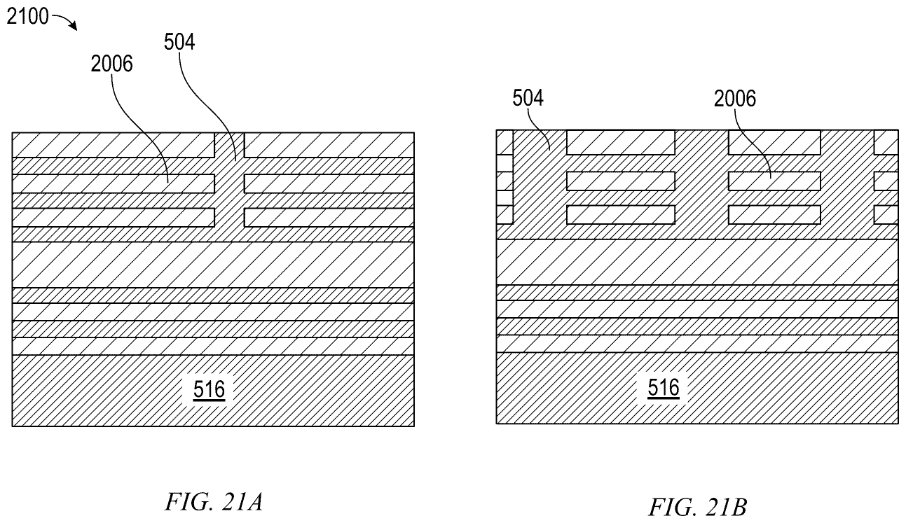

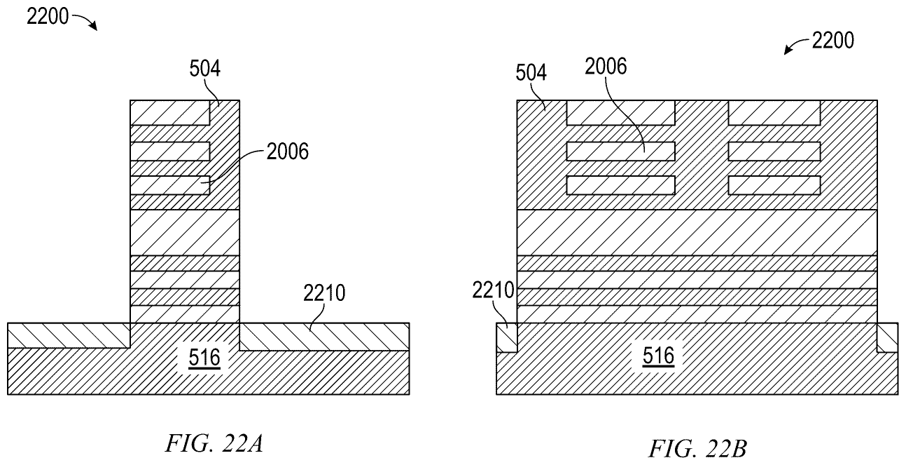

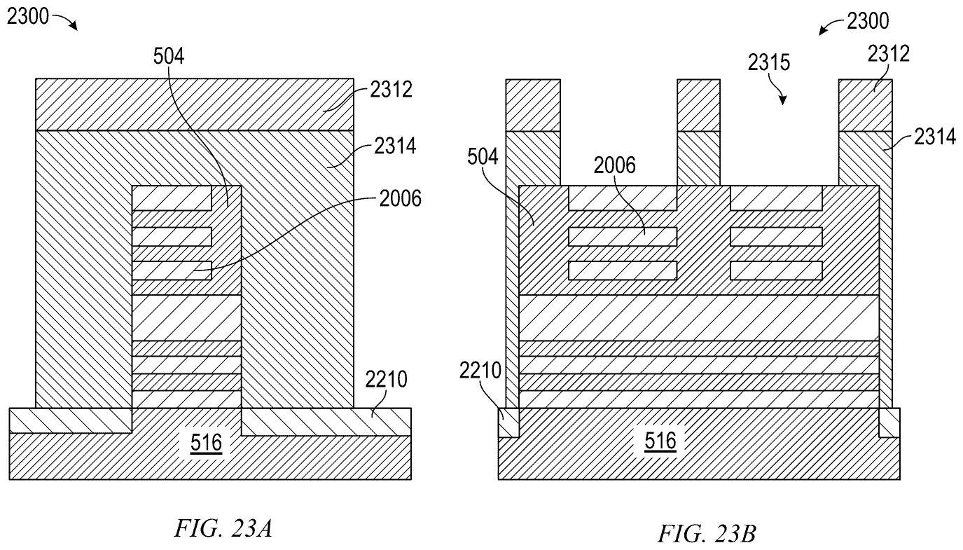

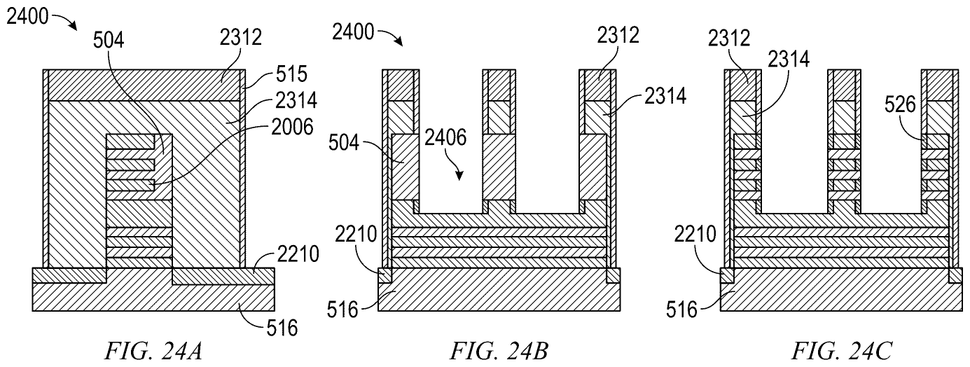

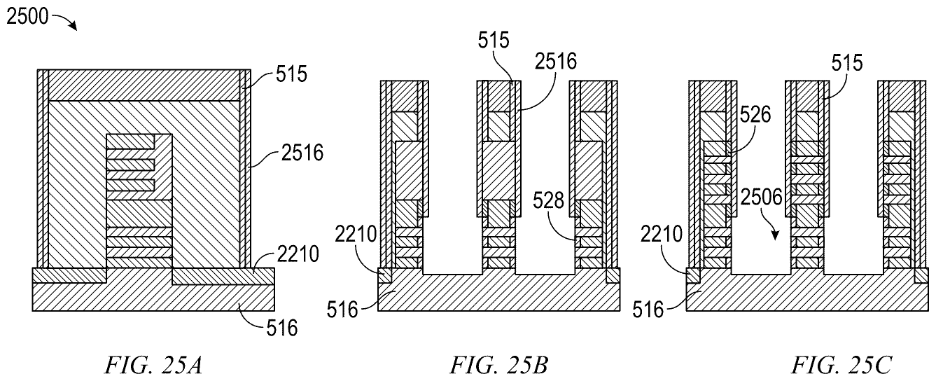

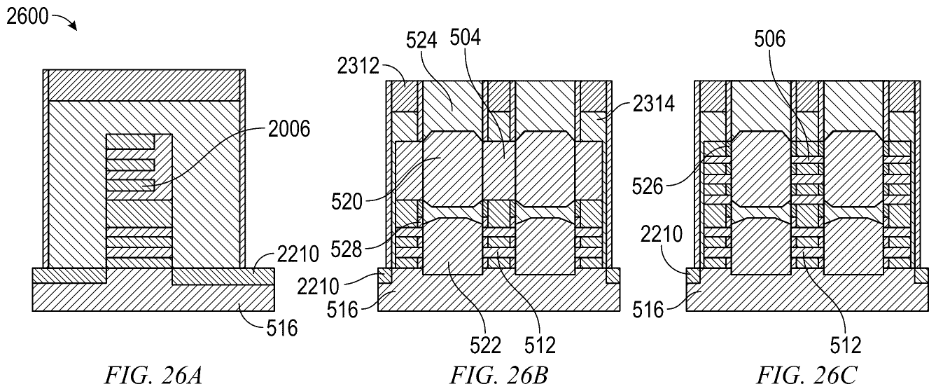

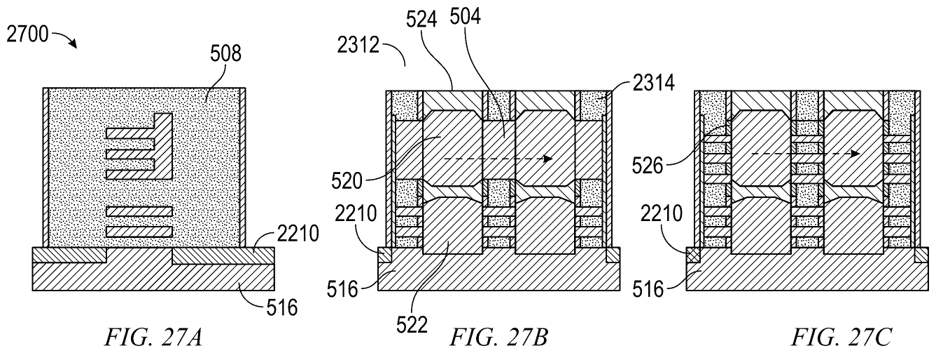

FIG. 20A, 20B, 21A, 21B, 22A, 22B, 23A, 23B, 24A, 24B 24C, 25A, 25B, 25C, 26A, 26B, 26C, 27A, 27B, 27C depict intermediate structures in a method of making the stacked combsheet FET that is shown in FIG. 5, 5A, 5B, 5C.

FIG. 20A, 20B depict an intermediate structure 2000 that has trenches 2002 that are formed in a stack of nanosheets 512 and sacrificial semiconductor layers 2006 atop the substrate 516. A hardmask 2004 has been lithographically patterned and etched to permit etching of the trenches through corresponding gaps in the hardmask.

FIG. 21A, 21B depict an intermediate structure 2100, in which fins 504 have been formed to fill the trenches 2002 that were shown in FIG. 20A, 20B.

FIG. 22A, 22B depict an intermediate structure 2200, in which the stack of nanosheets 512 has been further etched to form an island with the fin 504, and shallow trench isolation (STI) 2210 has been formed adjacent the base of the island.

FIG. 23A, 23B depict an intermediate structure 2300, in which a dummy gate 2314 and a hardmask 2312 have been deposited, patterned, and etched to form trenches 2315.

FIG. 24A, 24B, 24C depict an intermediate structure 2400, in which the trenches 2315 that were shown in FIG. 23A, 23B have been lined with a liner 515 and then further etched to form deeper and narrower trenches 2406 between the fins 504. These trenches eventually will be filled with source/drain structures 520, 522 as shown in FIG. 5B, 5C. Additionally, sacrificial layers 2006 have been recessed from the sidewalls of the trenches 2406 and dielectric spacers 526 have been formed.

FIG. 25A, 25B, 25C depict an intermediate structure 2500 in which sacrificial liner 2516 has been formed to protect the spacers 526, and then: trenches 2506 have been etched, the sacrificial layers 2006 have been recessed below the liner 2516, and additional spacers 528 have been formed.

FIG. 26A, 26B, 26C depict an intermediate structure 2600 in which the trenches 2506 have been filled with source/drain structures 520, 522 and interlayer dielectric 524.

FIG. 27A, 27B, 27C depict an intermediate structure 2700 in which gate stack 508 has been replaced the dummy gate 2314.

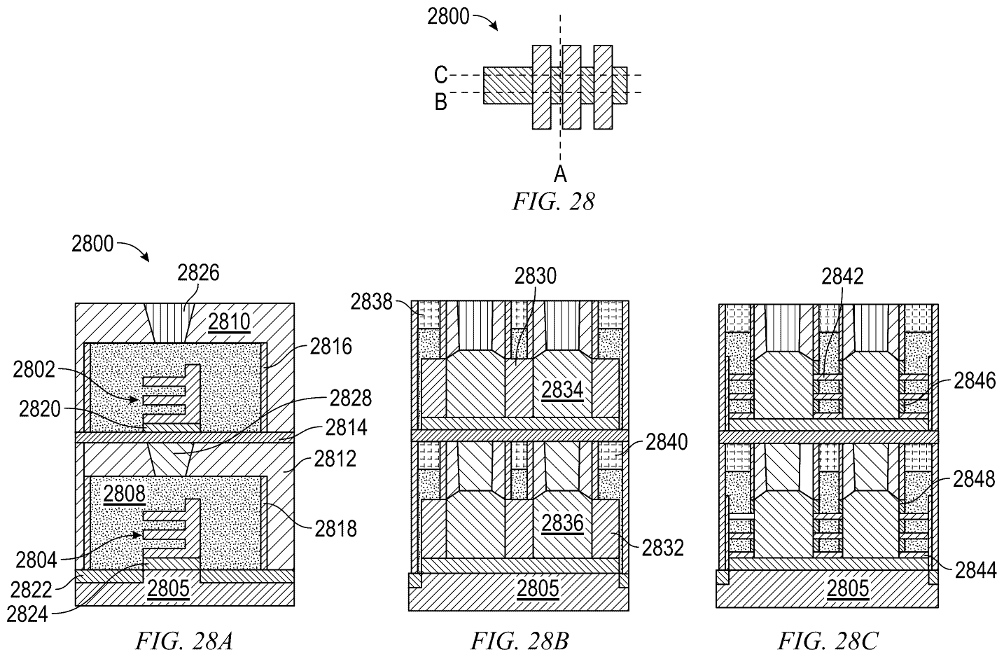

FIG. 28, 28A, 28B, 28C depict a bonded wafer structure of a stacked combsheet FET 2800, according to exemplary embodiments. As will be discussed further below with respect to FIG. 31, the FET 2800 is formed by providing a bonding wafer 3100, inverting same and bonding the inverted bonding wafer onto a structure including a first combsheet FET 3000, and then forming an upper combsheet FET (not labeled in FIG. 31; constituting structures 2802, 2806 in FIGS. 28A, 28B, 28C) in the bonding wafer 3100. The finished combsheet FET 2800, which is shown in FIGS. 28, 28A, 28B, 28C, includes an upper combsheet channel structure 2802 and a lower combsheet channel structure 2804, atop a substrate 2805. The upper combsheet channel structure includes fins 2830 and nanosheets 2842 that protrude sideways from the fins. The lower combsheet channel structure includes fins 2832 and nanosheets 2844 that protrude sideways from the fins. A gate stack 2806 surrounds the upper combsheet channel structure and a gate stack 2808 surrounds the lower combsheet channel structure. Interlayer dielectrics 2810, 2812 surround the gate stacks 2806, 2808. A bonding layer 2814 attaches the two wafers of the FET 2800. Liners 2816, 2818 separate the gate stacks from the interlayer dielectrics. Bottom dielectric isolator 2820 separates the upper combsheet channel structure 2802 from the bonding layer 2814, and bottom dielectric isolator 2822 separates the lower combsheet channel structure 2804 from the substrate 2805. Shallow trench isolation (STI) 2824 isolates the combsheet FET 2800 from adjoining FETs (not shown). The gate stacks 2806, 2808 are energized via metallic contacts 2826, 2828. The upper and lower channel structures 2802, 2804 electrically connect upper and lower source/drain structures 2834, 2836. Dielectric self-aligned cap (SAC) structures 2838, 2840 insulate portions of the gate stacks in a manner familiar to the skilled worker. Dielectric spacers 2846, 2848 separate the upper and lower gate stacks 2806, 2808 from the upper and lower channel structures 2802, 2804.

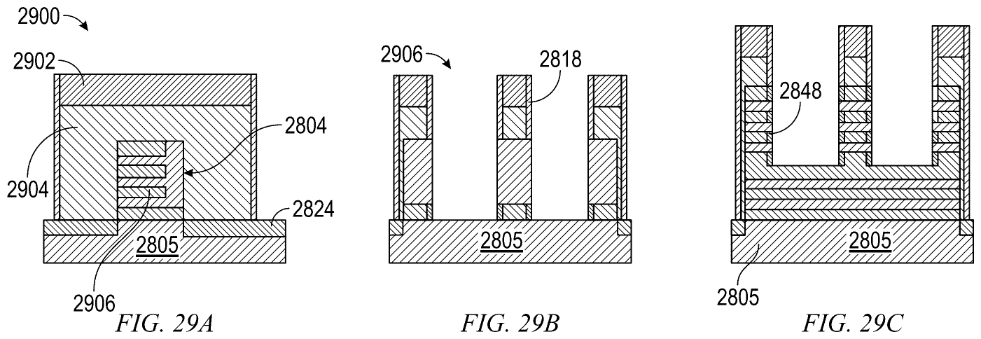

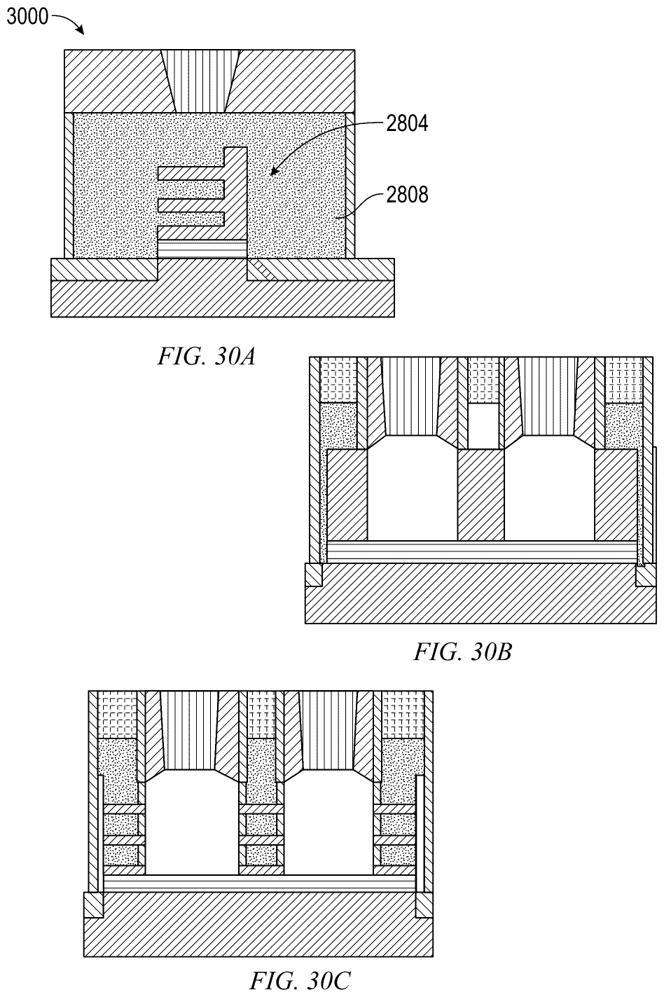

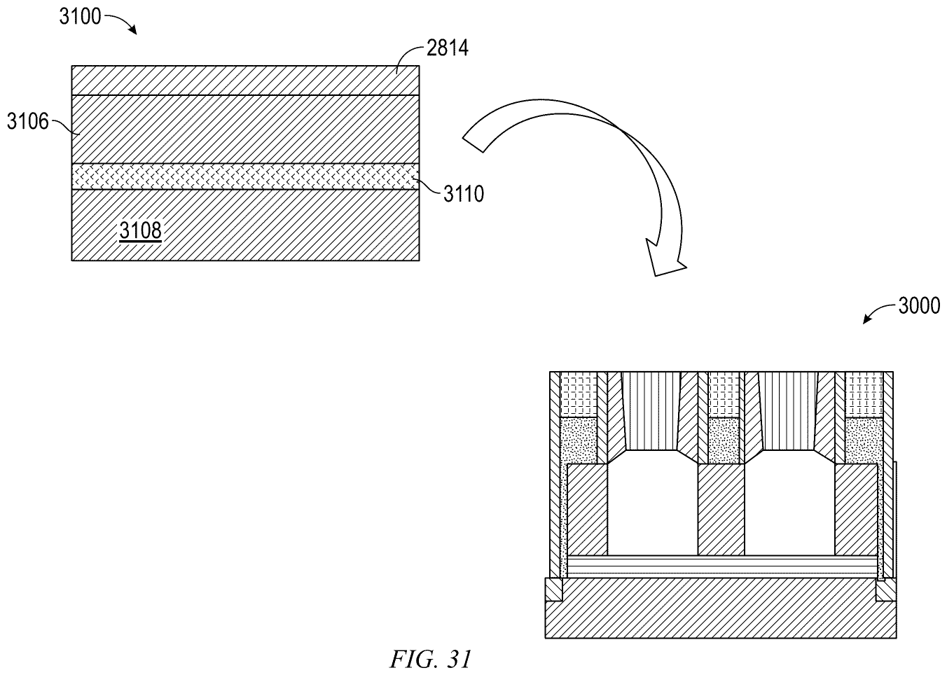

FIG. 29A, 29B, 29C, 30A, 30B, 30C, 31 depict intermediate structures in a method of making the stacked combsheet FET that is shown in FIG. 28, 28A, 28B, 28C.

Intermediate structure 2900, as shown in FIG. 29A, 29B, 29C, includes the lower combsheet channel structure 2804 epitaxially grown from the substrate 2805. Intermediate structure 2900 also includes sacrificial layers 2906 (i.e., layers of a semiconductor that etches preferentially to the combsheet channel structure 2804). A dummy gate 2904 surrounds the lower combsheet channel structure 2804, and a hardmask 2902 covers the dummy gate 2904. The hardmask 2902 is patterned and etched down through the dummy gate 2904, forming trenches 2906. In a subsequent step, the trenches 2906 will be filled with source/drain structures 2836 and interlayer dielectric 2812 (shown, e.g., in FIG. 28B, 30B). Along with etching the trenches 2906, liner 2818, STI 2824, and spacers 2848 are formed.

FIG. 30A, 30B, 30C depict an intermediate structure 3000, in which the gate stack 2808 has replaced the dummy gate 2904, bottom dielectric isolator 2822 has been formed, and the source/drain structures 2836 and the interlayer dielectric 2812 have been formed to fill the trenches 2906. Metal contacts 2828 also have been formed.

FIG. 31 depicts a step in which a bonding wafer 3100 is inverted and bonded to the structure 3000 that is shown in FIG. 30. The bonding wafer 3100 includes layered nanosheets 3106, a substrate 3108 (typically silicon, from which the nanosheets 3106 have been epitaxially grown), and an etch stop layer 3110 between the substrate and the nanosheets. After processing the bonding layer 2814 to bond the bonding wafer 3100 to the intermediate structure 3000 (e.g., by thermal anneal, thermocompression bonding, or other conventional methods of wafer bonding), further steps are performed on the inverted wafer 3100 to form the upper combsheet channel structure 2802 and its surrounding structures. These further steps will be apparent to the skilled worker, given the teachings herein, and therefore are not described in detail. For example, the further steps include repeating (on the additional wafer 3100) some or all of the steps shown in FIGS. 20A, 20B, 21A, 21B, 22A, 22B, 23A, 23B, 24A, 24B, 24C, 25A, 25B, 25C, 26A, 26B, 26C, 29A, 29B, 29C, 30A, 30B, 30C.

Given the discussion thus far, it will be appreciated that, in general terms, an exemplary integrated circuit structure 500 includes a first combsheet field effect transistor (FET) 502, which includes: a semiconductor substrate 516; a first plurality of semiconductor nanosheets 506, which in one or more embodiments are epitaxially grown from the substrate, that extend along a <101> crystallographic direction and that have horizontal surfaces oriented in (100) crystallographic planes and vertical sidewalls oriented in (110) crystallographic planes; and a semiconductor fin 504, which in one or more embodiments is epitaxially grown from the (110) crystallographic plane sidewalls of the nanosheets, that is integrally attached to the nanosheets, extends along the nanosheets, and has horizontal sidewalls oriented in (100) crystallographic planes and vertical surfaces oriented in (110) crystallographic planes.

In one or more embodiments, an exemplary integrated circuit structure 600 also includes a second combsheet FET 610 that is vertically stacked with a first combsheet FET 602.

In one or more embodiments, an exemplary integrated circuit structure 1100 includes a second combsheet FET 1110 that is of a different shape than a first combsheet FET 1102.

In one or more embodiments, an exemplary integrated circuit structure 1400 includes one of a first combsheet 1402 and a second combsheet 1410 that has a top end of its fin aligned flush with an upper surface of its upper nanosheet.

In one or more embodiments, an exemplary integrated circuit structure 900 includes one of the first and second combsheet FETs 902, 910 that has a peak at a top end of its fin.

In one or more embodiments, an exemplary integrated circuit structure 1200 includes one of the first and second combsheet FETs 1202, 1210 that has a top end of its fin that protrudes above an upper surface of its upper nanosheet.

In one or more embodiments, the second combsheet FET is of a different chemical composition than the first combsheet FET.

In one or more embodiments, an exemplary integrated circuit structure 1000 includes a nanosheet FET 1002 that is vertically stacked with the first combsheet FET 1010. The nanosheet FET 1002 includes a second plurality of semiconductor nanosheets that extend along the <110> direction and that have horizontal surfaces oriented in (100) planes and vertical sidewalls oriented in (110) planes. In one or more embodiments, the nanosheet FET 1002 is stacked vertically above the first combsheet FET 1010. In one or more embodiments, the nanosheet FET is of a different chemical composition than the first combsheet FET.

In one or more embodiments, the fin of the first combsheet FET has a peaked upper surface.

In one or more embodiments, the upper surface of the fin of the first combsheet FET protrudes above a topmost nanosheet of the first combsheet FET.

In one or more embodiments, the lower surface of the fin of the first combsheet FET protrudes below a bottommost nanosheet of the first combsheet FET.

In one or more embodiments, the fin of the first combsheet FET is disposed centrally along the nanosheets of the first combsheet FET.

In one or more embodiments, the first combsheet FET is a gate-all-around FET.

In one or more embodiments, an exemplary integrated circuit structure 2800 includes a second combsheet FET 2802 that is stacked vertically with the first combsheet FET 2804; and a bonding layer 2814 that mechanically joins the first combsheet FET to the second combsheet FET.

In one or more embodiments, an exemplary integrated circuit structure includes a nanosheet FET stacked vertically with the first combsheet FET; and a bonding layer that mechanically joins the nanosheet FET to the first combsheet FET.

Another aspect provides a method for forming a combsheet field effect transistor (FET). The method includes providing a semiconductor substrate 516; epitaxially growing, from the semiconductor substrate, a first plurality of stacked semiconductor nanosheets 506, 512 that are interleaved with a first plurality of stacked sacrificial layers 2006, by alternately depositing a first semiconductor that forms the nanosheets and depositing a sacrificial semiconductor that forms the sacrificial layers between the nanosheets; etching a trench 2002 into the stacked plurality of semiconductor nanosheets and sacrificial layers; and epitaxially growing a semiconductor fin 504 from sidewalls of the nanosheets into the trench, such that vertical surfaces of the fin are oriented in (110) crystallographic planes and horizontal surfaces of the nanosheets are oriented in (100) crystallographic planes, such that the fin and the nanosheet integrally attached to the fin compose the combsheet FET.

In one or more embodiments, the method also includes epitaxially growing, from the first plurality of stacked semiconductor nanosheets, a second plurality of stacked semiconductor nanosheets that are interleaved with a second plurality of stacked sacrificial layers.

In one or more embodiments, the method also includes inverting a bonding wafer 3100; attaching the bonding wafer to an upper surface of the combsheet FET; and forming a gate-all-around combsheet FET in the bonding wafer.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An integrated circuit structure comprising:
a first combsheet field effect transistor (FET), which comprises:
a semiconductor substrate;
a first plurality of semiconductor nanosheets that extend along a <101> crystallographic direction and that have horizontal surfaces oriented in (100) crystallographic planes and vertical sidewalls oriented in (110) crystallographic planes; and
a semiconductor fin that is integrally attached to the nanosheets, extends along the nanosheets, and has horizontal sidewalls oriented in (100) crystallographic planes and vertical surfaces oriented in (110) crystallographic planes.

2. The structure as claimed in claim 1, further comprising:
a second combsheet FET vertically stacked with the first combsheet FET.

3. The structure as claimed in claim 2, wherein the second combsheet FET is of a different shape than the first combsheet FET.

4. The structure as claimed in claim 2, wherein one of the first and second combsheets has a top end of its fin aligned flush with an upper surface of its upper nanosheet.

5. The structure as claimed in claim 2, wherein one of the first and second combsheet FETs has a peak at a top end of its fin.

6. The structure as claimed in claim 2, wherein one of the first and second combsheet FETs has a top end of its fin that protrudes above an upper surface of its upper nanosheet.

7. The structure as claimed in claim 2, wherein the second combsheet FET is of a different chemical composition than the first combsheet FET.

8. The structure as claimed in claim 1, further comprising:
a nanosheet FET vertically stacked with the first combsheet FET, wherein the nanosheet FET comprises:
a second plurality of semiconductor nanosheets that extend along the <110> direction and that have horizontal surfaces oriented in (100) planes and vertical sidewalls oriented in (110) planes.

9. The structure as claimed in claim 8, wherein the nanosheet FET is stacked vertically above the first combsheet FET.

10. The structure as claimed in claim 8, wherein the nanosheet FET is of a different chemical composition than the first combsheet FET.

11. The structure as claimed in claim 1, wherein the fin of the first combsheet FET has a peaked upper surface.

12. The structure as claimed in claim 1, wherein the upper surface of the fin of the first combsheet FET protrudes above a topmost nanosheet of the first combsheet FET.

13. The structure as claimed in claim 1, wherein the lower surface of the fin of the first combsheet FET protrudes below a bottommost nanosheet of the first combsheet FET.

14. The structure as claimed in claim 1, wherein the fin of the first combsheet FET is disposed centrally along the nanosheets of the first combsheet FET.

15. The structure as claimed in claim 1, wherein the first combsheet FET is a gate-all-around FET.

16. The structure as claimed in claim 1, further comprising:
a second combsheet FET stacked vertically with the first combsheet FET; and
a bonding layer that mechanically joins the first combsheet FET to the second combsheet FET.

17. The structure as claimed in claim 1, further comprising:
a nanosheet FET stacked vertically with the first combsheet FET; and
a bonding layer that mechanically joins the nanosheet FET to the first combsheet FET.

18. A method for forming a combsheet field effect transistor (FET), the method comprising:
providing a semiconductor substrate;
epitaxially growing, from the semiconductor substrate, a first plurality of stacked semiconductor nanosheets that are interleaved with a first plurality of stacked sacrificial layers, by alternately depositing a first semiconductor that forms the nanosheets and depositing a sacrificial semiconductor that forms the sacrificial layers between the nanosheets;
etching a trench into the stacked plurality of semiconductor nanosheets and sacrificial layers; and
epitaxially growing a semiconductor fin from sidewalls of the nanosheets into the trench,
such that vertical surfaces of the fin are oriented in (110) crystallographic planes and horizontal surfaces of the nanosheets are oriented in (100) crystallographic planes,
such that the fin and the nanosheet integrally attached to the fin compose the combsheet FET.

19. The method as claimed in claim 18, further comprising:
epitaxially growing, from the first plurality of stacked semiconductor nanosheets, a second plurality of stacked semiconductor nanosheets that are interleaved with a second plurality of stacked sacrificial layers.

20. The method as claimed in amended claim 18, further comprising:
inverting a bonding wafer;
attaching the bonding wafer to an upper surface of the combsheet FET; and
forming a gate-all-around combsheet FET in the bonding wafer.
